(19) United States
(12) Patent Application Publication
(10) Pub. No.: US 2019/0047848 A1
(43) Pub. Date: Feb. 14, 2019

(54) MEMS DEVICES AND PROCESSES

(71) Applicant: Cirrus Logic International Semiconductor Ltd., Edinburgh (GB)

(72) Inventor: Tsjerk Hans HOEKSTRA, Balerno (GB)

(73) Assignee: Cirrus Logic International Semiconductor Ltd., Edinburgh (GB)

(21) Appl. No.: 16/052,081

(22) Filed: Aug. 1, 2018

Related U.S. Application Data
(60) Provisional application No. 62/544,162, filed on Aug. 11, 2017.

(30) Foreign Application Priority Data
Sep. 5, 2017 (GB) 1714233.2

(51) Int. Cl. B81B 7/02; H04R 1/08; B81B 7/00; B81B 3/00

(52) U.S. Cl. CPC B81B 7/02; H04R 1/08; B81B 7/0032; B81B 3/0018; H04R 2201/003; B81B 2201/0257; B81B 2203/0315; B81B 2203/04; B81B 2203/0127; B81B 2201/047

(57) ABSTRACT

The application describes an assembly for a MEMS transducer comprising a substrate and a membrane, wherein the membrane is formed so as to have a curved surface region.

### TECHNICAL FIELD

This application relates to micro-electro-mechanical system (MEMS) devices and processes, and in particular to a MEMS device and process relating to a transducer, for example a capacitive or optical transducer.

### BACKGROUND INFORMATION

MEMS devices are becoming increasingly popular. MEMS transducers, and especially MEMS capacitive microphones, are increasingly being used in portable electronic devices such as mobile telephone and portable computing devices.

Microphone devices formed using MEMS fabrication processes typically comprise one or more moveable membranes and a static backplate, with a respective electrode deposited on the membrane(s) and backplate, wherein one electrode is used for read-out/drive and the other is used for biasing. A substrate supports at least the membrane(s) and typically the backplate also. In the case of MEMS pressure sensors and microphones the read out is usually accomplished by measuring the capacitance between the membrane and backplate electrodes. In the case of transducers, the device is driven, i.e. biased, by a potential difference provided across the membrane and backplate electrodes.

FIGS. 1a and 1b show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1a the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110. A plurality of holes, hereinafter referred to as bleed holes 111, connect the first cavity 109 and the second cavity 110. The bleed holes act to equalise the pressure between the first cavity 109 and the second cavity 110, and may also be referred to as pressure equalisation holes.

A plurality of acoustic holes 112 are arranged in the back-plate 104 so as to allow free movement of air molecules through the back plate, such that the second cavity 110 forms part of an acoustic volume with a space on the other side of the back-plate. The membrane 101 is thus supported between two volumes, one volume comprising cavities 109 and substrate cavity 108 and another volume comprising cavity 110 and any space above the back-plate. These volumes are sized such that the membrane can move in response to the sound waves entering via one of these volumes. Typically the volume through which incident sound waves reach the membrane is termed the “front volume” with the other volume being referred to as a “back volume”. Typically, for MEMS microphones and the like, the first and second volumes are connected by one or more flow paths, such as small holes in the membrane, that are configured so as present a relatively high acoustic impedance at the desired acoustic frequencies but which allow for low-frequency pressure equalisation between the two volumes to account for pressure differentials due to temperature changes or the like.

In some applications the backplate may be arranged in the front volume, so that incident sound reaches the membrane via the acoustic holes 112 in the backplate 104. In such a case the substrate cavity 108 may be sized to provide at least a significant part of a suitable back-volume. In other applications, the microphone may be arranged so that sound may be received via the substrate cavity 108 in use, i.e. the substrate cavity forms part of an acoustic channel to the membrane and part of the front volume. In such applications the backplate 4 forms part of the back-volume which is typically enclosed by some other structure, such as a suitable package.

It should also be noted that whilst FIGS. 1a and 1b shows the backplate being supported on the opposite side of the membrane to the substrate, arrangements are known where the backplate is formed closest to the substrate with the membrane layer supported above it.

In use, in response to a sound wave corresponding to a pressure wave incident on the microphone, the membrane is deformed slightly from its equilibrium or quiescent position. The distance between the membrane electrode 102 and the backplate electrode 103 is correspondingly altered, giving rise to a change in capacitance between the two electrodes that is subsequently detected by electronic circuitry (not shown).

The membrane layer and thus the flexible membrane of a MEMS transducer generally comprises a thin layer of a dielectric material—such as a layer of crystalline or polycrystalline material. The membrane layer may, in practice, be formed by several layers of material which are deposited in successive steps. Thus, the flexible membrane 101 may, for example, be formed from silicon nitride Si₃N₄ or polysilicon. Crystalline and polycrystalline materials have high strength and low plastic deformation, both of which are highly desirable in the construction of a membrane. The membrane electrode 102 of a MEMS transducer is typically a thin layer of metal, e.g. aluminium, which is typically located in the centre of the flexible membrane 101, i.e. that part of the membrane which displaces the most. It will be appreciated by those skilled in the art that the membrane electrode may be formed by depositing a metal alloy such as aluminium-silicon for example. The membrane electrode may typically cover, for example, around 40% of area of the membrane, usually in the central region of the membrane.

In some applications or arrangements it may be desirable for the membrane to exhibit greater strength and/or stiffness. For example, there is a tendency according to some transducer designs for the size of the transducer, in particular the size of the back volume, to be reduced. As a consequence, the air within the back volume can compress less and can thus be considered to be stiffer. Such designs require the transducer to be provided with a stiffer membrane in order to alleviate the risk that the membrane will fail and/or become damaged.

Thus, it may be desirable to provide a stronger membrane in conjunction with such transducer designs.

The present disclosure relates to MEMS transducers which seek to provide a flexible membrane having increased strength and/or stiffness.

### SUMMARY OF EMBODIMENTS

According to an example embodiment of a first aspect there is provided an assembly for a MEMS transducer, the assembly comprising a membrane wherein the membrane is formed so as to exhibit a substantially domed shape.

According to an example embodiment of a second aspect there is provided an assembly for a MEMS transducer comprising a substrate and a membrane, wherein the membrane is formed so as to have a curved surface region.

Thus the membrane is formed or engineered so that at least a portion of the surface of the membrane is inherently curved. In other words, the curved surface shape is an intrinsic characteristic of the membrane i.e. at least a part of the membrane surface is intrinsically curved.

It will be appreciated that the membrane exhibits first and second opposing or complimentary surfaces. The first surface may be considered to be the surface which directly faces, or borders, the front volume of a transducer. Thus the first surface may be the surface of the membrane on which pressure waves are incident in use. The second surface can be considered to directly face, or border, the back volume of a transducer.

It will be appreciated that there are occasions when the flexible membrane of a MEMS transducer may temporarily exhibit a degree of curvature as a consequence of a pressure differential across the membrane. Furthermore, a composite membrane and membrane electrode structure may also exhibit a degree of curvature following the high temperature deposition of the metal electrode layer on a surface of the membrane. This is a consequence of the membrane and membrane electrode having greatly different thermal expansion coefficients which gives rise to mechanical stress, and thus deformation, within the structure as the layers—which are intimately mechanically coupled together—contract by different amounts after fabrication. Thus, according to the examples described herein, it is convenient to consider the form of the membrane in a preliminary state. The preliminary state will typically comprise conditions that are different to the conditions arising when the assembly is part of a transducer in use—in other words when the assembly is in a working or in-use state. Specifically, a preliminary state can be considered to be a state where a substantially equilibrium pressure exists across the membrane, i.e. when the pressure exerted on the first surface of the membrane is substantially the same as the pressure exerted on the second surface of the membrane. The preliminary state can additionally be considered to be a state where the central region or flexible portion of the membrane (i.e. the portion of the membrane that is able to move or flex in response to a changing pressure differential across the membrane) is substantially free of any coupling or load, such as a metal electrode or an optical waveguide on a surface thereof.

According to one or more example embodiments, the membrane exhibits a curved, profiled or domed shape when in a preliminary state.

It will be appreciated that a curved surface may take a variety of forms. For example, one surface of the membrane may be considered to be at least partially concave whilst the other surface of the membrane may be considered to be at least partially convex. According to one example, the first surface of the membrane—i.e. the surface which directly faces or borders the front volume of the transducer—is convex whilst the second surface of the membrane—i.e. the surface which directly faces or borders the back volume of the transducer—is concave. According to another example, the first surface of the membrane is concave whilst the second surface of the membrane is convex.

According to one or more embodiments the membrane is supported relative to a substrate. Thus, the membrane may be pinned or anchored to an upper surface of the substrate, or may extend into one or more side walls that form a part of, or are attached to, the substrate. Thus, the membrane is supported relative to the substrate so as to define a flexible membrane portion. The membrane may be provided so as to overlie a cavity formed through the substrate. In particular, the flexible portion of the membrane at least partially overlies the cavity in the substrate.

According to one or more examples, at least a portion of the flexible membrane portion is shaped to exhibit an inherently domed shape.

According to one or more examples, the membrane further comprises a planar (i.e. substantially flat) region. The planar region may be laterally outside a perimeter which defines the boundary of the curved or domed surface region. Thus, the planar region may surround the curved surface region. The planar region of the membrane may at least partially overlie an upper surface of the substrate. Thus, the membrane may be supported at the planar region by the substrate.

According to an example embodiment of a third aspect there is provided an assembly for a MEMS transducer, the assembly being composed of a substrate and a membrane, wherein the membrane is formed so as to be non-planar (i.e. not flat) when the pressure exerted on the first surface of the membrane is substantially equal to the pressure exerted on the second surface of the membrane.

According to an example embodiment of a further aspect there is provided a MEMS transducer comprising an assembly according to any of the examples or aspects described herein and a sensing mechanism for detecting movement of the flexible membrane to pressure waves incident on the flexible membrane.

The sensing mechanism may comprise a capacitive sensing mechanism. Thus, a first metal electrode is provided on a surface of the membrane. A second metal electrode may be provided a fixed distance from the first electrode when a time-varying pressure differential across the membrane is negligible.

Alternatively, the sensing mechanism comprises an optical sensing mechanism. Thus, the membrane further comprises an electromagnetic waveguide. The electromagnetic waveguide may be formed integrally with the flexible membrane. The electromagnetic waveguide may be an optical waveguide. The optical waveguide may be configured to guide light having wavelengths of between 400 nm and 1600 nm.

Associated methods of fabricating a MEMS transducer are provided for each of the above aspects and examples described herein.

According to an example embodiment of a further aspect there is provided a method of forming an assembly for a MEMS transducer, comprising:

providing a substrate;
forming a membrane layer relative to the substrate such that the membrane layer comprises a domed region.

The method may further comprise:

providing a body of sacrificial material on a surface of the substrate;
processing the body of sacrificial material so as to form a curved upper surface region;
wherein the step of forming the membrane layer comprises depositing a layer of membrane material on top of the body of sacrificial material.

According to an example embodiment of a further aspect there is provided an assembly comprising a substrate and a membrane layer supported with respect an upper surface of the substrate, wherein a portion of the membrane layer is formed so as to define a chamber between the upper surface of the substrate and a lower surface of the membrane layer. The chamber may be sealed.

Features of any given aspect may be combined with the features of any other aspect and the various features described herein may be implemented in any combination in a given embodiment.

### FIGURES

For a better understanding of the present invention and to show how the same may be carried into effect, reference will now be made, by way of example, the accompanying drawings in which:

FIGS. 1a and 1b illustrate known capacitive MEMS transducers in section and perspective views;

FIGS. 2a, 2b and 2c each illustrates a cross sections through an example assembly for a MEMS transducer;

FIG. 3 illustrates an assembly for a MEMS transducer;

FIG. 4 illustrates a cross section through a MEMS transducer according to one example which relies upon a capacitive sensing mechanism;

FIGS. 5a and 5b show arrangements wherein the back volume of the transducer comprises a substantially sealed chamber;

FIG. 6 illustrates a cross section through a MEMS transducer according to a further example wherein the transducer comprises an unperforated membrane;

FIGS. 7a and 7b illustrate optical sensing mechanisms;

FIG. 8 illustrates further optical sensing mechanisms;

FIG. 9 illustrates a MEMS microphone transducer according to a further example which relies upon an optical sensing mechanism;

FIG. 10 is a plot to illustrate the variation in intensity with membrane deflection for capacitive and optical sensing systems;

FIGS. 11a to 11d illustrate a sequence of steps according to an example method for forming an assembly;

FIGS. 12a to 12d illustrate a sequence of steps according to a further example method for forming an assembly; and

FIGS. 13a to 13f illustrate a sequence of steps according to a further example method for forming an assembly.

The drawings may not be to scale and are for the purpose of illustration only.

### DETAILED DESCRIPTION

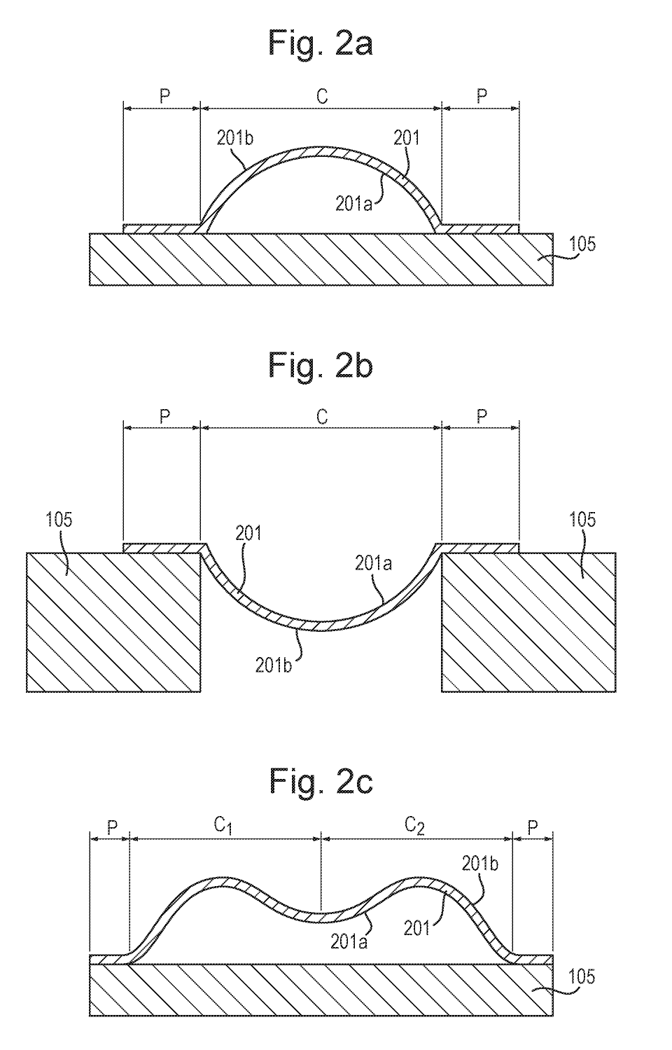

FIG. 2a illustrates a cross section through an example assembly for a MEMS transducer comprising a substrate 105 and a membrane 201. The membrane comprises a non-planar region C. Thus, the non-planar region of the membrane exhibits a substantially domed shape. Thus, the domed shape is formed by a curved surface region of the membrane. A further region of the membrane comprises a planar region P. In this example the planar region is provided laterally outside a perimeter which defines the boundary of the curved surface region. In other words, the planar region surrounds the curved surface region. The planar region can be considered to form a planar perimeter region of the membrane. The planar region of the membrane at least partially overlies an upper surface of the substrate 105. Thus, in this embodiment, the membrane is supported at the planar region by the substrate 105. The membrane comprises first and second complimentary/opposing surfaces 201a and 201b. Within the curved surface region, the first surface 201a of the membrane which will directly borders the front volume of the eventual transducer, is concave (in other words with respect to the upper surface of the substrate 105 to which the membrane is attached), whilst the second surface 201b—when considered from the region above the membrane—of the membrane is convex.

FIG. 2b illustrates a cross section through a further example assembly for a MEMS transducer comprising a substrate 105 and a membrane 201. In the example shown in FIG. 2b the first surface of the membrane 201a is convex with respect to the upper surface of the substrate 105, to which the membrane is attached, whilst the second surface 201b of the membrane is concave with respect to the upper surface of the substrate 105. Again, the membrane comprises a planar perimeter region. The substrate is provided with a cavity 108 which extends through the substrate in a direction substantially normal to the plane of the substrate from a first surface to a second surface thereof. The curved surface region of the membrane 201 is provided so as to overlie the cavity 108.

The substrate may typically be formed of silicon e.g. a silicon die that is formed as part of a silicon wafer. The flexible membrane may comprise a crystalline or polycrystalline material, such as one or more layers of silicon-nitride Si₃N₄ or polysilicon.

FIGS. 2a and 2b illustrate the assembly in a preliminary state wherein a substantially equilibrium pressure exists across the membrane. Thus, it will be appreciated that the membrane curvature that is demonstrated in the curved surface region of the membrane is an inherent feature of the membrane, rather than being a consequence of a differential pressure across the membrane or due to any other factors such as temperature, stress, loading or attachment to the membrane of other components of the transducer etc. It will be appreciated that the assembly may be modified during a further processing step—for example by forming a cavity through the substrate and/or by incorporating one or more components of a sensing mechanism to allow detection of the movement of the membrane in use and/or by incorporating the assembly in a package.

The domed or inherently curved shape of the membrane layer, even at substantially equilibrium pressure conditions and without any load on the membrane layer, gives rise to a number of advantages. In particular, it will be appreciated that the domed, e.g. nonplanar, shape of the membrane imparts structural and/or geometrical strength to the membrane structure. Thus, the membrane is inherently stronger and/or stiffer than a flat or planar membrane having the same dimensions. This increased strength of the membrane may be beneficially utilised in a number of applications and MEMS transducer designs. For example, as a consequence of the increased strength it is possible to provide a MEMS transducer membrane having a reduced thickness as compared to planar membrane designs without any detriment to the robustness of the membrane. Furthermore, a number of transducer designs e.g. transducer designs having a relatively small back volume—may require or at least benefit from a stronger membrane in order to manage the risk of membrane damage or failure. This can be achieved, according to examples described herein, by the provision of membrane having a curved or non-planar surface region and, preferably, without the need to thicken the membrane which may reduce flexibility of the membrane and, thus, the sensitivity of the transducer.

According to example embodiments the membrane may comprise a plurality of curved surface regions. FIG. 2c illustrates a cross-sectional view of a further example assembly for a MEMS transducer comprising a substrate 105 and a membrane 201. The membrane comprises a planar region P and a non-planar region C. The non-planar region comprises two, distinct, curved surface regions C1 and C2. Each of the curved surface regions comprises a dome wherein the first surface of the membrane 201a is concave with respect to the upper surface of the substrate 105.

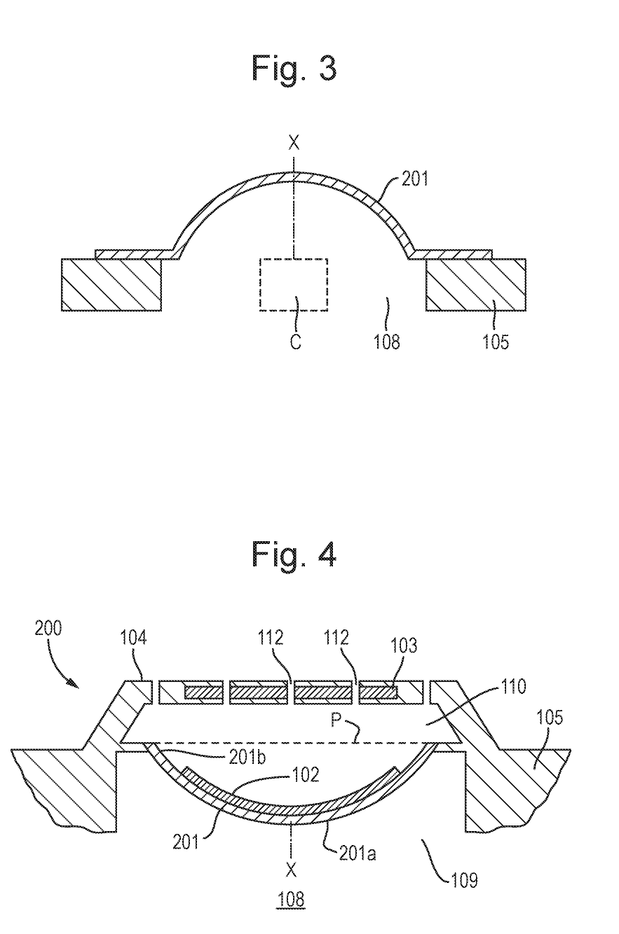

FIG. 3 illustrates an assembly for a MEMS transducer. The assembly is similar to the assembly illustrated in FIG. 2a, however, the substrate is provided with a cavity 108 which extends through the substrate in a direction substantially normal to the plane of the substrate from a first surface to a second surface thereof. The curved surface region of the membrane 201 is provided so as to overlie the cavity 108. According to one or more examples the highest point X of the curved surface region may overlie a central region C of the substrate cavity.

In some example embodiments the curved surface can be considered to define a portion of a notional, enclosed solid shape. The notional shape may be a perfect sphere (i.e. a shape in which every point is an equal distance from the centre). In the case of a membrane which exhibits a curved surface portion which is a portion of a notional sphere, it is possible to consider the radius of curvature of the curved surface by considering the radius of circle that fits a normal section (i.e. the intersection of the surface with a normal plane) of the surface. It will be appreciated that in this case, first and second mutually orthogonal, diametric, normal sections of the surface will intercept at the highest point of the curved surface region.

With this in mind, and referring back to FIGS. 2a and 2b which illustrate cross-sectional views of example assemblies, it will be appreciated that these figures effectively illustrate a normal section through the curved surface of the membrane.

According to example embodiments a MEMS transducer may be provided having an assembly, the assembly being composed of a substrate and a membrane having a non-planar surface region, as well as a sensing mechanism for detecting movement of the flexible membrane to pressure waves incident on the flexible membrane.

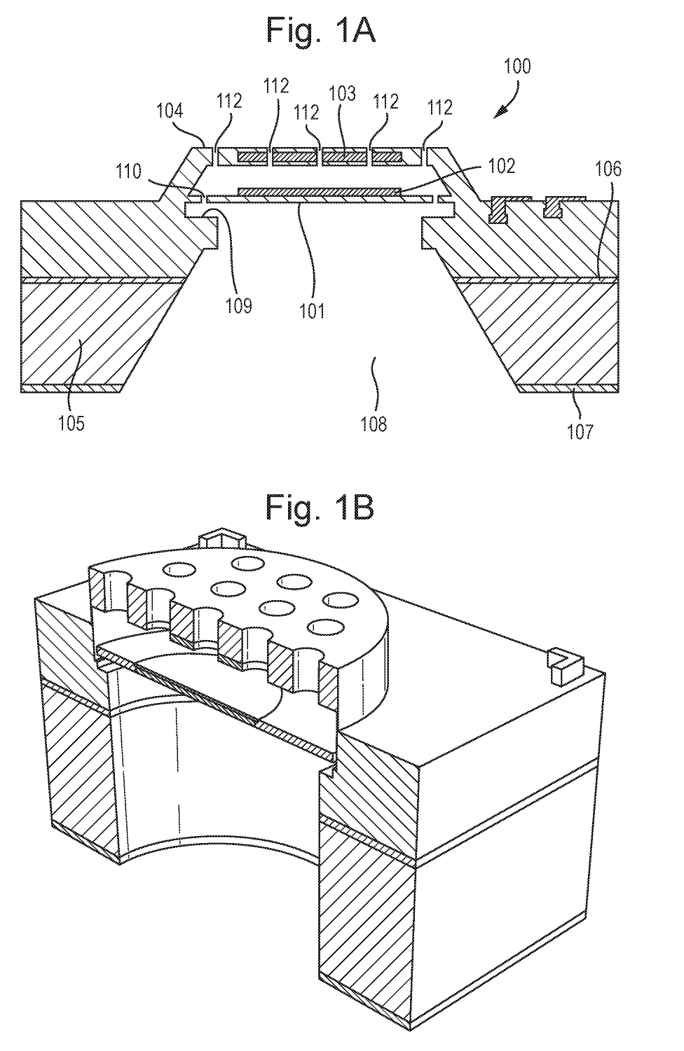

FIG. 4 illustrates a cross section through a MEMS transducer 200 according to one example which relies upon a capacitive sensing mechanism similar to the mechanism utilised by the capacitive microphone device 100 shown in FIG. 1a. Specifically FIG. 4 illustrates a MEMS transducer comprising a membrane 201 which is supported relative to the substrate to define a flexible membrane which is free to move in response to pressure differences generated by sound waves. A first electrode 102 is mechanically coupled to the flexible membrane 201, and together they form a first capacitive plate of the capacitive microphone device. A second electrode 103 is mechanically coupled to a generally rigid structural layer or back-plate 104, which together form a second capacitive plate of the capacitive microphone device.

The membrane 201 comprises a curved surface region wherein membrane is not co-planar with the plane of the rest of the membrane region and instead defines a generally dome-shaped region. Thus, the first surface of the membrane 201a is convex whilst the second surface 201b of the membrane is concave. The curvature of the curved surface region of the membrane is a consequence of the manner in which the membrane layer itself has been formed/fabricated during a method of making an assembly comprising a substrate and a membrane. Thus, it will be appreciated that the degree or amount of curvature of the membrane is significantly greater than the relatively minor deformation of the membrane that may occur following the deposition of the membrane electrode.

A cavity 108 in the substrate is provided in a plane underlying the membrane such that the highest point X of the curved flexible membrane region is overlapping with a central region of the cavity. It will be appreciated that the “highest point” shall be taken to be the point furthest away from the plane P of the rest of the membrane layer. This may be the point where the gradient of the normal section of the surface that is illustrated in FIG. 4 changes direction (goes to zero).

In any of the examples described herein the flexible membrane region, which is defined by the manner in which the membrane layer is supported relative to the substrate or side walls of the assembly/transducer, may preferably be circular. Such a design may beneficially provide a uniform tension around the periphery of the flexible membrane. However, other flexible membrane shapes are envisaged including square/rectangular or “cow-hide”.

The transducer illustrated in FIG. 4 may be conveniently located within a package (not shown) which defines a package chamber and comprises an acoustic port to allow entry of acoustic pressure waves into the package. Thus, the MEMS transducer will be provided within the package such that pressure waves which enter the package via the sound port are incident on the first surface of the curved surface region of the membrane.

Examples described herein find particular application in transducer designs wherein the back volume is reduced for some reason, e.g. to provide a reduced overall package height, which effectively stiffens the air in the sense gap between the membrane electrode and the backplate electrode. Specifically, the provision of a domed membrane effectively strengthens and/or stiffens the membrane to ensure the membrane is still compatible within the stiffer sense gap without needing to thicken the membrane (which would undermine the membrane flexibility and thus the sensitivity of the device).

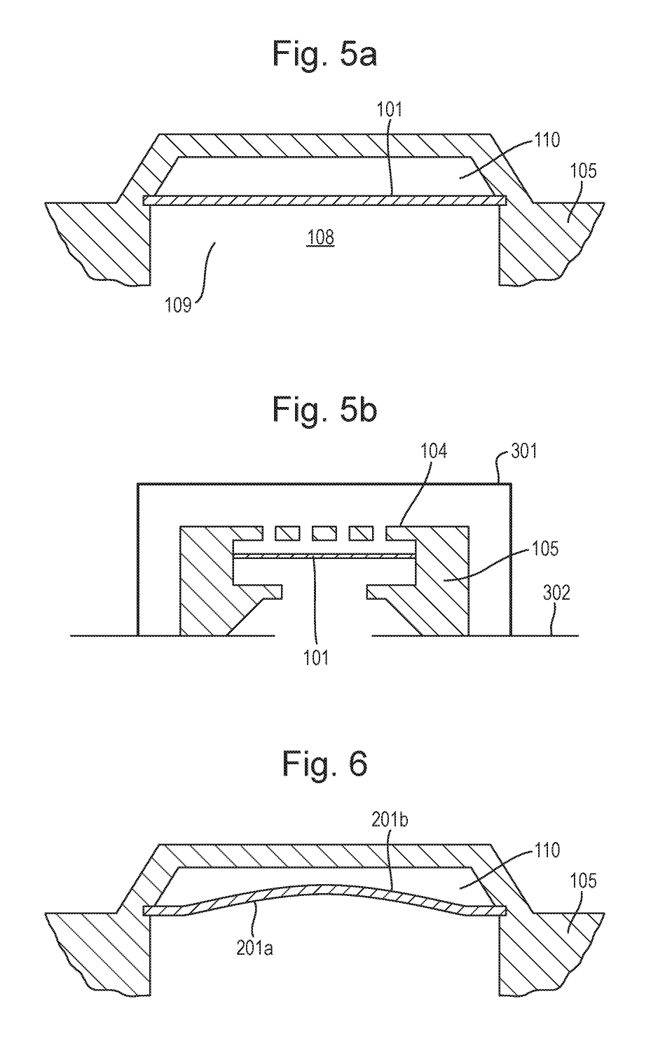

Assemblies and transducers described herein find particular application to arrangements whereby the first side of the flexible membrane is fluidically isolated from the second side of the flexible membrane 101. An example of such an arrangement is illustrated in FIG. 5a. Further details of this aspect, and the advantages thereof, can be found in greater detail in co-pending application P3270 being filed concurrently by the present Applicant.

Whereas in previously considered designs the flexible membrane typically comprises one or more perforations, such as bleed holes and/or vents, which allow fluid communication between the front volume 109 of the transducer and the back volume 110, or sense gap, of the transducer, FIG. 5a shows an arrangement wherein the back volume 110 comprises a substantially sealed back chamber. The sealed chamber 110 is partially defined by the upper surface of the membrane—i.e. one of the walls of the chamber is formed by the membrane which is supported relative to the substrate 105 and/or side walls of the transducer. It will be noted that the membrane does not comprise any perforations and can thus be considered to be an unperforated membrane. Thus, substantially no fluid (air or gas) can flow between the front volume and the back volume. In other words, there are no flow paths (including flow paths having a high acoustic impedance) through the membrane. The sealed chamber may be further defined by a backplate structure of the transducer (which may support a backplate electrode and wherein the backplate structure does not comprise any acoustic holes or other perforations) or—as illustrated in FIG. 5b—by the top plate or lid 301 of a package having a substrate 302 within which the transducer is housed.

In MEMS microphones, one of the key considerations is the signal-to-noise ratio (SNR) provided by the microphone. Reducing the level of noise on a signal (and thereby improving the SNR) can improve the accuracy of recorded sound. Noise can be generated within the structure of the MEMS device by the interaction of air molecules on solid structures within the MEMS device (boundary layer noise) or due to the interaction of air molecules with each other (thermal noise). Another dominant source of noise within MEMS microphones is due to the movement of air molecules through a comparatively narrow gap. Examples of such are the movement of air molecules through acoustic holes in the back plate or though bleed holes, i.e. pressure equalisation holes, in the membrane.

Thus, MEMS transducers such as the example illustrated in FIGS. 5a and 5b which incorporate a sealed back chamber 110 wherein the back chamber is fluidically isolated from the region outside the chamber, benefit from a reduction in the noise that would otherwise be generated by the movement of fluid between region on the first side of the membrane and the region on the second side of the membrane.

As a consequence of the fluidic isolation of the back chamber, it will be appreciated that it is possible for the chamber to contain a constant (i.e. unchanging) number of particles or amount of gas. It will be further appreciated that the amount of noise generated by boundary layer noise and acoustic thermal noise is proportional to the kinetic energy of the air molecules involved in the collisions (that is, collisions with the surrounding surfaces and each other respectively), which in turn is proportional to the mass of the molecules involved. Accordingly, the amount of noise generated by both boundary layer noise and acoustic thermal noise can be reduced by replacing the air in the sealed chamber with a gas having a lower molecular weight than air. In this way, for a given temperature, the kinetic energy of the different gas molecules will be less than that of air molecules at the same given temperature, and the noise attributed to the collision of the molecules with interior surfaces of the chamber and with other molecules will beneficially be reduced.

Accordingly, helium or other gases which are lighter than air, such as neon, may be selected as a suitable gas to fill the back volume. The mean molecular weight of helium is 4 grams per mole (the atomic weight of helium is 4), while air is primarily composed of nitrogen and oxygen and has a mean molecular weight in the region of 28.97 grams per mole. Accordingly, filling the back volume with helium instead of air can significantly reduce the total kinetic energy of the molecules in the back volume, thereby reducing boundary layer noise and acoustic thermal noise.

In addition to, or alternatively to, reducing the mean molecular weight of the gas in the chamber, the total kinetic energy (and hence boundary layer noise and acoustic thermal noise) may be reduced by reducing the amount of gas in the chamber. This is equivalent to reducing the pressure in the chamber (all other conditions such as the temperature of the gas and the volume of the chamber being equal). Reducing the amount of gas in the chamber reduces the frequency of collisions between the gas molecules and between gas molecules and the surrounding structures. Accordingly the constant amount of gas in the chamber may be set such that, at standard temperature and pressure (approximately 273 K and 1.01×10⁵ kgm⁻¹s⁻², that is, 0° C. and 101 kPa) the gas in the chamber is at a lower pressure than the pressure in the region outside the chamber.

In order to minimise boundary layer noise and acoustic thermal noise as far as possible, the chamber 110 may be exhibit a lower pressure than the region surrounding the chamber. According to a particular example, the chamber may be a vacuum (that is, the constant amount of gas in the chamber is zero gas). Alternatively, the chamber may be at a pressure level of approximately 1 kgm⁻¹s⁻², that is, 1 Pa. Assuming that the region surrounding the chamber is at normal atmospheric pressure of around 1.01×10⁵ kgm⁻¹s⁻², this chamber pressure level significantly reduces the boundary layer noise and acoustic thermal noise relative to maintaining the chamber at the same pressure as the surrounding atmosphere.

It will be appreciated that, according to one or more examples which utilise a sealed back chamber as illustrated in FIG. 5a or 5b, the pressure exerted on the first side of the membrane may be different to the pressure exerted on the second side of the membrane. This constant differential pressure will give rise to a constant force acting on the membrane which can potentially result in the membrane failing or becoming damaged.

FIG. 6 illustrates a cross section through a MEMS transducer according to a further example wherein the transducer comprises an unperforated membrane having a curved surface portion. Thus, the membrane comprises a portion which is inherently dome-shape which is non-planar. Thus, in this example, the first surface of the membrane 201a is concave with respect to the upper surface of the substrate whilst the second surface 201b of the membrane is convex with respect to the upper surface of the substrate. The transducer illustrated in FIG. 6 is similar to the transducer illustrated in FIG. 5a in that the back volume of the transducer 110 comprises a sealed chamber. A fixed number of particles (which may be zero) are contained within the sealed chamber. Thus, in addition to the improvement in SNR that is achieve as a consequence of the sealed chamber 110, the FIG. 6 example further benefits from a membrane having increased strength and/or stiffness. The increased geometric strength of the flexible membrane region which arises as a consequence of the inherently domed shape of the membrane beneficially mitigates the likelihood of the membrane suffering damage due to a constant pressure differential across the membrane.

The FIG. 6 example may rely upon a capacitive sensing mechanism to detect motion of the flexible membrane caused by pressure waves incident on the first side of the membrane. The capacitive sensing mechanism using electrodes (not illustrated) may be similar to the mechanism utilised by the capacitive microphone device 100 shown in FIG. 1a and as discussed above in relation to FIG. 4.

Alternatively, one or more examples including the examples illustrated in FIG. 4 and FIG. 6, may utilise an optical sensing mechanism instead of electrodes. The use of an optical sensing system will be discussed in more detail below.

The movement of air molecules through and around the back-plate can be a significant source of noise for MEMS transducers configured to operate as microphones. Therefore the absence of a back-plate structure can significantly improve the SNR. However, capacitive microphones operate by measuring the capacitance between a pair of electrodes, one of said electrodes being mounted on the back-plate. As such, the removal of the back-plate necessitates a different sensing mechanism to capacitive sensing. Such an optical transducer is described in United Kingdom Patent Application No. 1705492.5 filed by the present Applicant.

As explained more fully in United Kingdom Patent Application No. 1705492.5 in optical microphone systems, an electromagnetic wave emitter, such as a Light Emitting Diode (LED) or a semiconductor laser, is used to generate electromagnetic radiation. Typically, although not exclusively, electromagnetic radiation in the visible region of the electromagnetic spectrum is generated.

The generated electromagnetic radiation is then carried by an electromagnetic waveguide, which moves with the flexible membrane. The electromagnetic waveguide may be formed integrally with the flexible membrane, that is, the electromagnetic waveguide and flexible membrane may be formed from substantially the same material as a single piece. The electromagnetic waveguide may be configured to constrain the propagation of electromagnetic waves of a given wavelength range (the electromagnetic wave emitter is selected to generate electromagnetic radiation in the applicable wavelength range). The electromagnetic waveguide may be a rib-type waveguide and protrude from a surface of the flexible membrane, or may be a graduated refractive index-type waveguide which constrains electromagnetic radiation using variations in the refractive index of a material and may be formed within the membrane.

The operation of the optical microphone is based on the principle that the movement of the flexible membrane (comprising the electromagnetic waveguide) due to incident sound/pressure waves alters the properties of electromagnetic waves within the electromagnetic waveguide. This alteration can be detected using an electromagnetic detector, such as a photodiode or photomultiplier tube, and used to deduce the properties of the incident sound wave.

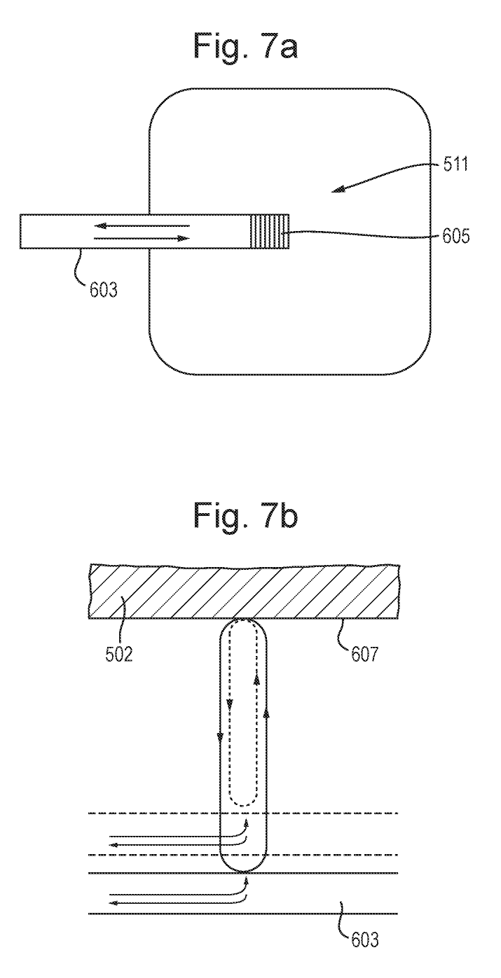

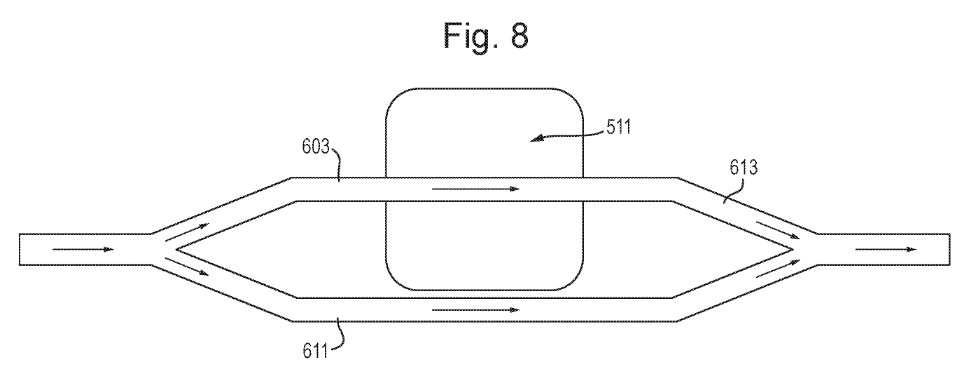

Various different configurations can be used to effect optical microphone systems, and different properties of the electromagnetic radiation can be monitored by the electromagnetic detector. The electromagnetic detector may be configured to monitor the intensity of the detected electromagnetic radiation, the phase of the detected electromagnetic radiation, and so on. MEMS Optical microphone systems can be divided into systems which deflect the electromagnetic radiation out of the plane of the flexible membrane, and those which do not. FIG. 7a shows an example of a flexible membrane and electromagnetic waveguide of an optical microphone system which deflects the electromagnetic radiation out of the plane of the flexible membrane, and FIG. 8 shows an example of a system which does not deflect the electromagnetic radiation out of the plane of the membrane.

FIG. 7a shows a flexible membrane 511 and electromagnetic waveguide 603 terminating in an electromagnetic wave diverter 605 for use in an optical microphone. The operating principle is shown in FIG. 7b. This example utilises a configuration similar to that of a Fabry-Perot interferometer. In this example, the light that has propagated along the electromagnetic waveguide is diverted by an electromagnetic wave diverter 605 such as a diffraction grating (not shown in FIG. 7b), such that the electromagnetic wave is emitted from the waveguide. In this example, the electromagnetic wave diverter is configured to divert the electromagnetic waves through an angle of approximately 90°, such that waves which were previously propagating through the waveguide approximately parallel to a first surface of the flexible membrane (and along a primary axis of the waveguide) are coupled out of the waveguide, and are thus diverted to propagate at an angle normal to the first surface of the membrane at the point of emission.

Any suitable component can be used as the electromagnetic wave diverter, such as a grating or a membrane reflective surface at a particular angle with respect to a plane of the flexible membrane. Where the electromagnetic waves are to be diverted through an angle of approximately 90°, the membrane reflective surface is positioned at an angle of 45°. Gratings essentially require a series of precisely spaced grooves to be formed in a surface of the electromagnetic waveguide, and can therefore be formed without requiring any additional components to be incorporated into the system and to any required specifications. The grating can also act to allow electromagnetic waves to re-enter the electromagnetic waveguide if necessary. Use of a membrane reflective surface allows the diverted electromagnetic waves to be directed precisely as required (dependent on the angle of the membrane reflective surface with respect to the direction of propagation of the electromagnetic waves).

The diverted wave travelling away from the planar surface of the flexible membrane is then incident on a reflector 607 that is reflective to the wavelength range of the electromagnetic wave. The reflective surface of this example substantially parallel to the plane of the flexible membrane, and is further configured to reflect the electromagnetic wave that has been diverted by the diverter back towards the flexible membrane. Where a reflector is used, this can be located in any position that allows light to be reflected back towards the flexible membrane. Examples of suitable locations for a reflector include a substrate of a MEMS optical microphone device, or a package of a MEMS optical microphone device. In the example shown in FIG. 7a, the package 502 has been used. Configurations of the reflector are discussed in greater detail below, with reference to the general structure of the MEMS device.

The reflected electromagnetic wave then re-enters the waveguide. In the present embodiment, the reflected electromagnetic wave re-enters the same waveguide as the electromagnetic wave was diverted out of by the diverter. The re-entry of the electromagnetic wave into the waveguide is facilitated by the diverter, which is configured to again divert the electromagnetic waves through an angle of approximately 90°, such that electromagnetic waves are once again travelling substantially parallel to the planar surface of the flexible membrane and propagating along the electromagnetic waveguide. However, in alternative configurations, the reflector reflective surface may be configured to reflect the electromagnetic waves at a further waveguide (where the entry of the electromagnetic wave into the waveguide can be facilitated by a further diverter), or may be configured to reflect the electromagnetic wave directly at an electromagnetic wave detector. Where the reflected electromagnetic waves subsequently re-enter the electromagnetic waveguide, this reduces the number of required components, thereby simplifying the formation of the system.

The electromagnetic waves then exit the electromagnetic waveguide and encounter an electromagnetic wave detector (not illustrated), at which the wave is detected. The operating principle this example is illustrated by FIG. 7b. In FIG. 7b, the position of the electromagnetic waveguide and the path of the electromagnetic wave when the flexible membrane is in an undisturbed position is indicated by solid lines, and the position of the electromagnetic waveguide and the path of the electromagnetic wave when the flexible membrane has moved is indicated by the dashed lines. In this example, the movement of the flexible membrane (and the corresponding movement of the electromagnetic waveguide) causes the separation between the point of emission of the electromagnetic waves from the waveguide and the reflective surface of the reflector to vary. The electromagnetic waves are monochromatic, and are emitted at a given phase. The system is configured such that the separation between the point of emission of the electromagnetic waves and the reflective surface (multiplied by two, as the wave must travel both ways) results in a known shift in the phase of the electromagnetic wave. This phase shift is monitored at the electromagnetic wave detector, allowing the position of the membrane (and hence the properties of incident sound waves) to be deduced.

As discussed above, the example shown in FIGS. 7a and 7b relies on the deflection of the electromagnetic wave out of the plane of the membrane. FIG. 8 illustrates the principle of a further example, which does not rely on the deflection of the electromagnetic wave out of the plane of the membrane. This example uses a configuration which is similar in some respects to a Mach-Zehnder interferometer.

The configuration of the example illustrated by FIG. 8 utilises a beam splitter (not shown) to split monochromatic electromagnetic radiation emitted from an electromagnetic wave emitter into two portions. Any suitable beam splitting device can be used; the illustrated example uses a half silvered mirror. The two portions pass down two separate paths formed by one or more electromagnetic waveguides, before recombining at a recombination point. The first of these paths is a reference path 611, which passes from the beam splitter to the recombination point without passing over the flexible membrane 511. The second path is a sample path 613 that passes over the flexible membrane to reach the recombination point.

When the flexible membrane is in an undisturbed position, the lengths of the sample path 613 and the reference path 611 (between the beam splitter and the recombination point) are equal. Prior to splitting, the monochromatic electromagnetic radiation has a single phase. If the lengths of the sample path and the reference path remain the same (because the flexible membrane does not move as the electromagnetic radiation passes down the sample path and reference path), then the electromagnetic radiation sent down the sample path and the electromagnetic radiation sent down the reference path remain in phase with one another. By contrast, if the flexible membrane is moved from the undisturbed position while the electromagnetic radiation travels down the paths (due to incident sound waves), this increases the length of the sample path relative to an undisturbed position. Accordingly, the electromagnetic wave that passes along the sample path undergoes a phase shift relative to the electromagnetic wave that passes along the reference path, such that the two waves are no longer perfectly in phase with one another.

The electromagnetic waves recombine at the recombination point. If the electromagnetic wave that passed along the sample path has undergone a phase shift relative to the electromagnetic wave that passed along the reference path, the recombined waves will generate an interference pattern. Measurements of interference patterns resulting from the interaction of the wave from the reference path and the wave from the sample path allow a degree of phase shift to be detected, which in turn allows the deflection of the flexible membrane to be obtained.

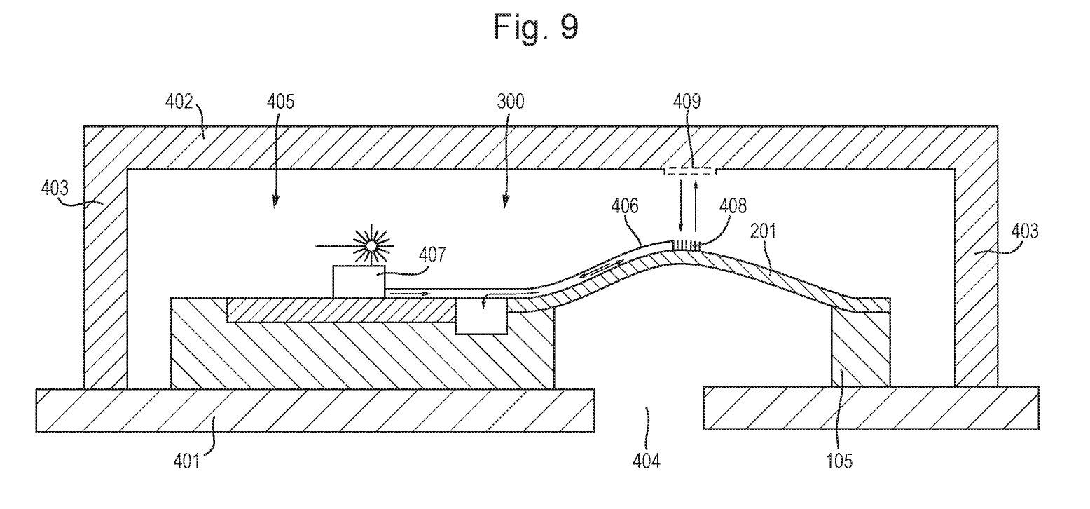

According to a further example aspect as illustrated in FIG. 9 a MEMS microphone transducer 300 is provided which relies upon optical sensing and further exhibits a membrane 201 which is formed to exhibit an inherently domed shape. Specifically, FIG. 9 illustrates a MEMS transducer 300 housed within a MEMS transducer package 400 comprising a bottom plate 401, a top plate 402 and side walls 403. The optical sensing system comprises an electromagnetic waveguide 406, an electromagnetic wave emitter 407 (e.g. an LED), a diffraction grating 406 and a reflector 409 spaced from the flexible membrane 201. The membrane 201 may be perforated to include e.g. bleed holes or vents. Alternatively, the membrane may be unperforated such that the back chamber 405 is substantially sealed and such that the first surface if the membrane is fluidically isolated from the second surface of the membrane.

The FIG. 9 example illustrates how the SNR can be improved by removing additional sources of noise from within an MEMS device. In the example shown in FIG. 9, the MEMS device does not include a back-plate structure. The absence of the back-plate mitigates the generation of noise due to the passage of air molecules through acoustic holes in the back-plate and also alleviates the generation of noise due to the movement of air molecules in the gap between the back-plate and the membrane.

It will be appreciated that the use of optical sensing techniques in the MEMS device is well suited to configurations employing a domed membrane shape due to the sensitivity of optical sensing techniques relative to capacitive sensing techniques, and the way in which optical sensing techniques can advantageously compensate for existing membrane curvature.

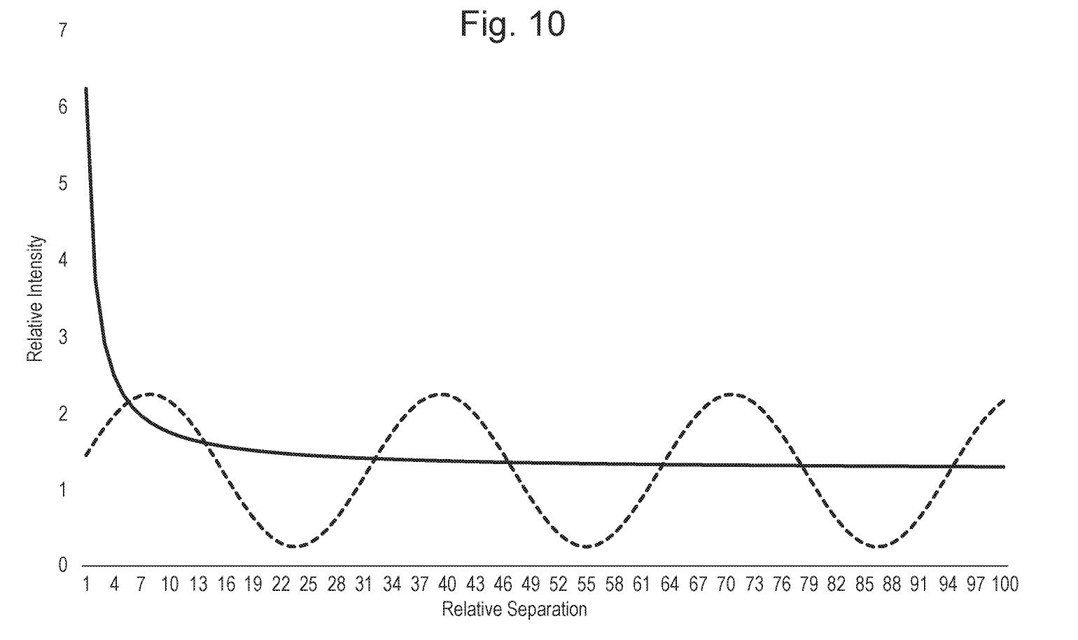

Capacitive sensing techniques operate by detecting variations in the capacitance between two electrodes. The capacitance between the two electrodes varies proportionally with the reciprocal of the separation between the electrodes, on a constant curve. When using optical techniques, the variation in the measured properties of the electromagnetic radiation (such as the intensity or phase shift) varies periodically with constantly changing separation. An example outline plot of the variation in intensity with membrane deflection for capacitive and optical sensing systems is shown in FIG. 10. In the plot, increasing membrane deflection provides increasing separation. For the capacitive system, the separation is between the two electrodes, while for the optical system the separation is between the point at which electromagnetic radiation is emitted from the waveguide on the flexible membrane and a reflector.

The plot in FIG. 10 illustrates that optical techniques can provide greater sensitivity across an entire range of membrane deflections. Also, optical sensing techniques generally allow a constant displacement in the membrane (prior to any incident sound waves) to be taken into account more easily. With reference to the plot in FIG. 10, if the membrane of the capacitive system is already subject to a significant variation from a planar position as a consequence of the membrane having an inherently domed shape, then the capacitance variation with the deflection due to a given incident sound waves will be comparatively small relative to if the same given sound wave had been incident on the membrane of the capacitive system without an existing significant deflection, and therefore the accuracy of detection may be reduced.

For an optical sensing system, the variation in the intensity of detected light caused by incident pressure waves on the membrane wave would be similar or the same regardless of whether the membrane was already under a significant deflection. Therefore, optical sensing systems are particularly well suited to use with the present configurations which utilise a domed flexible membrane.

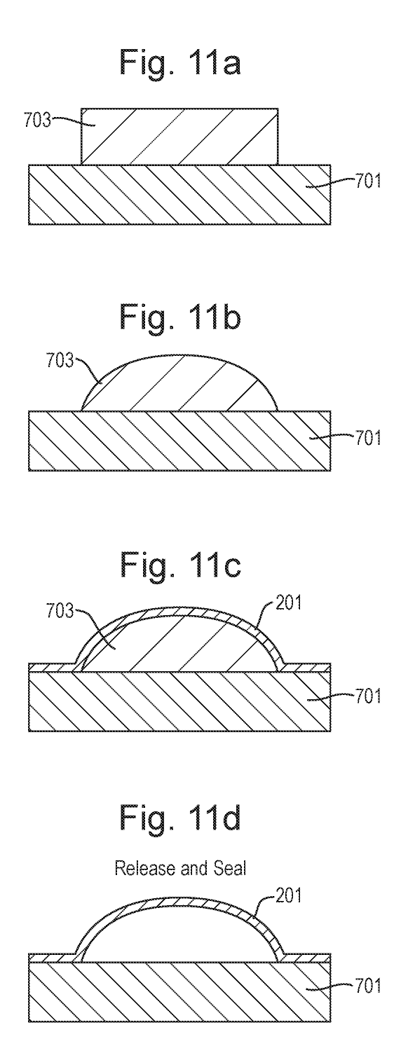

According to other aspects methods are provided for fabricating a MEMS transducer. FIGS. 11a to 11d illustrate a sequence of steps for forming an assembly comprising a substrate having a membrane which is formed to exhibit a domed shape.

As shown in FIG. 11a a substrate 701 (e.g. silicon) is provided. A sacrificial body of e.g. polyimide 703 is provided on the top surface of the substrate. The sacrificial body is then fluidised by subjecting to a thermal treatment and/or by performing e.g. an annealing or reflow process which, as illustrated in FIG. 11b, causes the sacrificial body to exhibit a curved outer surface as a consequence of the surface tension. As illustrated in FIG. 11c a layer of membrane material 201 (e.g. Silicon nitride) is deposited on the upper surface of the substrate and the sacrificial body. Subsequently, the sacrificial body is removed from the chamber that is defined by the membrane and the substrate to produce the assembly illustrated in FIG. 11d.

It will be appreciated that the “substrate” 701 may typically form the conventional substrate of a MEMS transducer (wherein a cavity is formed through the substrate which forms part of a front volume of the transducer). Alternatively, the substrate 701 may form a back structure (e.g. a backplate structure which may or may not comprise acoustic holes) of an eventual MEMS transducer device. Thus, in the case of the assembly illustrated in FIG. 11d, a cavity may be formed through the substrate such that the concave surface of the membrane forms the first surface of the membrane (i.e. the surface which borders the front volume of the transducer). Alternatively, the substrate 701 may form a backplate structure and the convex surface of the domed membrane forms the first surface of the membrane. In this case, if required—for example if the assembly is intended to form a membrane and sealed back chamber of a MEMS transducer in which sound waves are incident on the convex surface of the domed membrane—any perforations made in the membrane or in the substrate to release the sacrificial material are sealed.

Thus, according to a further aspect of the present invention there is provided an assembly comprising a substrate and a membrane layer supported with respect an upper surface of the substrate, wherein a portion of the membrane layer is formed so as to define a chamber between the upper surface of the substrate and a lower surface of the membrane layer. According to a preferred example of this aspect, the chamber is sealed.

As illustrated in the example illustrated in FIGS. 11a to 11d, it will be appreciated that a sacrificial polyimide layer deposited on a substrate surface can be partially cured or crosslinked making it suitable to pattern. This partially cured polyimide layer can then be patterned into e.g. rectangular, square or circular features with a substantially perpendicular sidewall by means of standard photolithography either using a resist or hard mask and followed by a dry plasma etch or a wet developer etch to remove the excess polyimide. The remaining polyimide feature can be exposed to a thermal treatment (e.g. reflow) whereby the volume of polyimide material is redistributed by surface tension to minimize the surface area resulting into a circular feature with the footprint of the original pattern. The shape can be locked-in by now fully curing or cross-linking the curved polyimide shape. By adjusting the volume of material (thickness) and footprint geometry the desired curvature can be achieved. Subsequently the desired dielectric layer is deposited by a plasma process (PVD) with a small hole. The polyimide sacrificial material can be removed by a plasma process through the small opening, after which this opening is coated and sealed under vacuum or at desired pressure.

As a consequence of the membrane being formed to exhibit a substantially dome-like shape—e.g. wherein the first surface and the second surface form a complimentary pair of curved surfaces—the resultant structure benefits from enhanced robustness e.g. to a constant pressure differential.

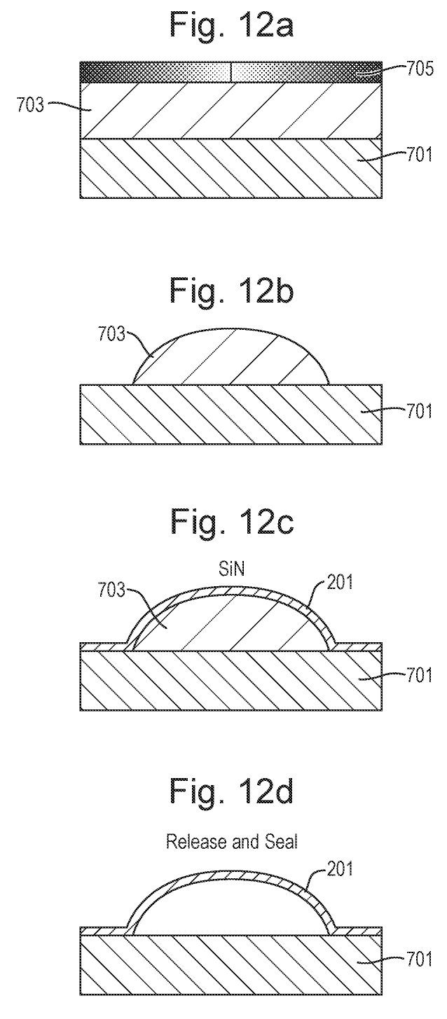

FIGS. 12a to 12d illustrate a further sequence of steps for forming an assembly comprising a substrate having a membrane which is formed to exhibit a domed shape.

The sequence steps are similar to the step illustrated in FIGS. 11a to 11d, except that in FIG. 12a a gradient mask or grey-scale mask is used in conjunction with a lithographic process to shape the upper surface of the body of sacrificial polyimide. In particular, a UV curable polyimide is utilised which is exposed through a grey-scale or gradient mask. The different levels of UV generate different crosslink densities. When developing the exposed polyimide areas with high cross-link density no material is removed whereas in areas with lower cross-link density more excess material is removed. This results in curved shape as shown in FIG. 12b which follows the UV intensity pattern as defined by the grey-scale mask. The processing steps illustrated in FIGS. 12c and 12d are substantially the same as the steps illustrated in FIGS. 11c and 11d.

The use of a grey scale mask potentially offers better control and customisation of the shape of the surface and allows for the formation of a range of non-planar or profiled surfaces having different profiles/topologies.

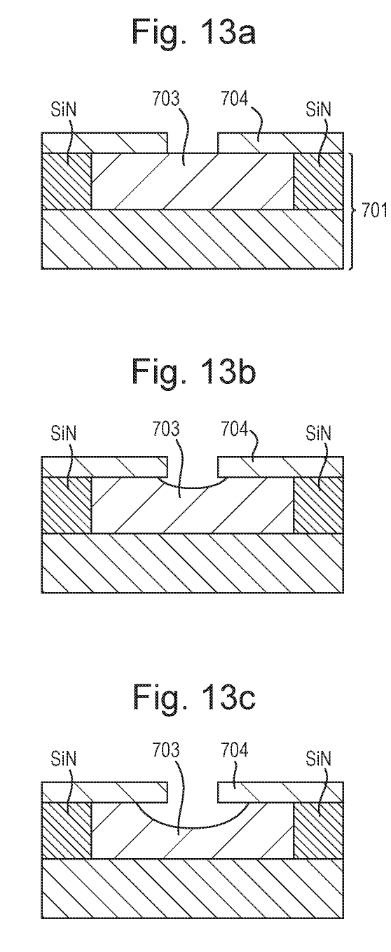

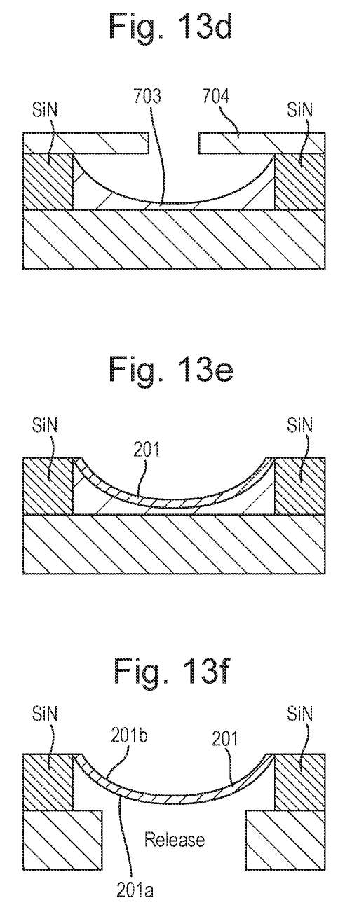

FIGS. 13a to 13f illustrate a further sequence of steps for forming an assembly comprising a substrate 701 having a membrane which is formed to exhibit a domed shape. A polyimide layer 703 is deposited on a substrate and is etched through a mask 704 by a plasma etch process which has a high selectivity of the polyimide relative to the mask material. Such a mask material may be a metal or a dielectric layer. Such a plasma etch process can be isotropic which means that the etch rate in horizontal direction is the same as in vertical direction. When the polyimide layer is exposed to such a plasma through the mask opening this results into a curved surface of the polyimide which propagates with time substantially equally in all directions maintaining its curvature. Through adjusting the plasma etch chemistry the horizontal and vertical etch rates can be manipulated and thus the shape of the curvature of the curved surface of polyimide can be controlled in conjunction with the shape of the opening of the etch mask. Subsequently, as illustrated in FIG. 13e a membrane layer is deposited onto the curved polyimide surface and is subsequently released via a cavity formed in the substrate 701. Thus, it will be appreciated that the process of etching the polyimide layer through a mask results in a domed membrane as illustrated in FIG. 13e which projects below the plane of the top surface of the substrate. In this example, the first surface of the membrane 201a is convex whilst the second surface 201b of the membrane is concave (though it will be appreciated that the remaining polyimide may be released without forming a cavity in the substrate such that the assembly form a backplate structure and the convex surface of the domed membrane forms the first surface of the membrane. In this case, if required—for example if the assembly is intended to form a membrane and sealed back chamber of a MEMS transducer in which sound waves are incident on the convex surface of the domed membrane—any perforations made in the membrane or in the substrate to release the sacrificial material are sealed.

According to further aspects there is provided a MEMS transducer comprising an assembly formed according to each of the methods described above.

The flexible membrane may comprise a crystalline or polycrystalline material, such as one or more layers of silicon-nitride Si₃N₄.

MEMS transducers according to the present examples will typically be associated with circuitry for processing an electrical signal generated as a result of detected movement of the flexible membrane, either by a capacitive sensing technique or by an optical sensing technique. Thus, in order to process an electrical output signal from the microphone, the transducer die/device may have circuit regions that are integrally fabricated using standard CMOS processes on the transducer substrate.

The circuit regions may be fabricated in the CMOS silicon substrate using standard processing techniques such as ion implantation, photomasking, metal deposition and etching. The circuit regions may comprise any circuit operable to interface with a MEMS transducer and process associated signals. For example, one circuit region may be a pre-amplifier connected so as to amplify an output signal from the transducer. In addition another circuit region may be a charge-pump that is used to generate a bias, for example 12 volts, across the two electrodes. This has the effect that changes in the electrode separation (i.e. the capacitive plates of the microphone) change the MEMS microphone capacitance; assuming constant charge, the voltage across the electrodes is correspondingly changed. A pre-amplifier, preferably having high impedance, is used to detect such a change in voltage.

The circuit regions may optionally comprise an analogue-to-digital converter (ADC) to convert the output signal of the microphone or an output signal of the pre-amplifier into a corresponding digital signal, and optionally a digital signal processor to process or part-process such a digital signal. Furthermore, the circuit regions may also comprise a digital-to-analogue converter (DAC) and/or a transmitter/receiver suitable for wireless communication. However, it will be appreciated by one skilled in the art that many other circuit arrangements operable to interface with a MEMS transducer signal and/or associated signals, may be envisaged.

It will also be appreciated that, alternatively, the microphone device may be a hybrid device (for example whereby the electronic circuitry is totally located on a separate integrated circuit, or whereby the electronic circuitry is partly located on the same device as the microphone and partly located on a separate integrated circuit) or a monolithic device (for example whereby the electronic circuitry is fully integrated within the same integrated circuit as the microphone).

Examples described herein may be usefully implemented in a range of different material systems, however the examples described herein are particularly advantageous for MEMS transducers having membrane layers comprising silicon nitride.

One or more MEMS transducers according to the examples described here may be located within a package. This package may have one or more sound ports. A MEMS transducer according to the examples described here may be located within a package together with a separate integrated circuit comprising readout circuitry which may comprise analogue and/or digital circuitry such as a low-noise amplifier, voltage reference and charge pump for providing higher-voltage bias, analogue-to-digital conversion or output digital interface or more complex analogue or digital signal processing.

A MEMS transducer according to the examples described here may be located within a package having a sound port.

It is noted that the example embodiments described above may be used in a range of devices, including, but not limited to: analogue microphones, digital microphones, pressure sensor or ultrasonic transducers. The example embodiments may also be used in a number of applications, including, but not limited to, consumer applications, medical applications, industrial applications and automotive applications. For example, typical consumer applications include portable audio players, laptops, mobile phones, PDAs and personal computers. Example embodiments may also be used in voice activated or voice controlled devices. Typical medical applications include hearing aids. Typical industrial applications include active noise cancellation. Typical automotive applications include hands-free sets, acoustic crash sensors and active noise cancellation.

Features of any given aspect or example embodiment may be combined with the features of any other aspect or example embodiment and the various features described herein may be implemented in any combination in a given embodiment.

Associated methods of fabricating a MEMS transducer are provided for each of the example embodiments.

It should be understood that the various relative terms above, below, upper, lower, top, bottom, underside, overlying, underlying, beneath, etc. that are used in the present description should not be in any way construed as limiting to any particular orientation of the transducer during any fabrication step and/or it orientation in any package, or indeed the orientation of the package in any apparatus. Thus the relative terms shall be construed accordingly.

In the examples described above it is noted that references to a transducer may comprise various forms of transducer element. For example, a transducer may be typically mounted on a die and may comprise a single membrane and back-plate combination. In another example a transducer die comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprise different individual transducers positioned to receive acoustic signals from different acoustic channels.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1.-45. (canceled)

46. An assembly for a MEMS transducer comprising a substrate and a membrane, wherein the membrane is formed so as to have a single curved surface region.

47. An assembly as claimed in claim 46, the membrane comprising first and second surfaces, wherein at the curved surface region of the membrane the first surface of the membrane exhibits a concave or convex shape and the second surface of the membrane respectively exhibits a convex or concave shape.

48. An assembly as claimed in claim 46, wherein a cavity is provided through the substrate and wherein the curved surface region of the membrane at least partially overlies the cavity in the substrate.

49. An assembly as claimed in claim 48, wherein the curved surface region comprises a highest point and wherein the highest point overlies a central region of the cavity.

50. An assembly as claimed in claim 46, wherein the membrane is supported relative to the substrate to define a flexible membrane region and wherein the curved surface region is at least partially within the flexible membrane region and optionally at a central region of the flexible membrane region.

51. An assembly as claimed in claim 46, wherein the curved surface region of the membrane defines a domed shape.

52. An assembly as claimed in claim 46, wherein the curved surface region defines a part of a sphere.

53. An assembly as claimed in claim 46, wherein the membrane exhibits the curved surface region at equilibrium when the pressure exerted on the first surface of the membrane is substantially equal to the pressure exerted on the second surface of the membrane.

54. An assembly for a MEMS transducer, the assembly being composed of a substrate and a membrane, wherein the membrane is formed so as to be non-planar when the pressure exerted on the first surface of the membrane is substantially equal to the pressure exerted on the second surface of the membrane and wherein the membrane has a curved surface region.

55. A MEMS transducer comprising the assembly of claim 46 and a sensing mechanism for detecting movement of the flexible membrane in response to pressure waves incident on the flexible membrane.

56. A MEMS transducer as claimed in claim 55, wherein the sensing mechanism comprises a capacitive sensing mechanism, and wherein a first metal electrode is provided on a surface of the membrane.

57. A MEMS transducer as claimed in claim 55, wherein the sensing mechanism comprises an optical sensing mechanism and wherein the membrane further comprises an electromagnetic waveguide formed integrally with the flexible membrane.

58. A MEMS transducer as claimed in claim 57, wherein the electromagnetic waveguide is an optical waveguide configured to guide light having wavelengths of between 400 nm and 1600 nm.

59. An assembly as claimed in claim 47, wherein the first surface of the flexible membrane is fluidically isolated from the second surface of the flexible membrane.

60. An assembly as claimed in claim 59, further comprising a chamber, wherein the second surface of the flexible membrane partially defines the boundary of the chamber, and wherein the chamber is fluidically isolated from a region outside the chamber.

61. An assembly as claimed in claim 60, wherein the chamber contains a constant amount of gas or is a vacuum.

62. A MEMS transducer comprising the assembly of claim 46 wherein said transducer comprises a microphone.

63. A MEMS transducer as claimed in claim 62, further comprising readout circuitry wherein the readout circuitry may comprise analogue and/or digital circuitry.

64. An electronic device comprising a MEMS transducer as claimed in claim 62 wherein said device is at least one of: a portable device; a battery powered device; an audio device; a computing device; a communications device; a personal media player; a mobile telephone; a games device; and a voice controlled device.

65. An assembly comprising a substrate and a membrane layer supported with respect an upper surface of the substrate, wherein a portion of the membrane layer is formed so as to define a sealed chamber between the upper surface of the substrate and a lower surface of the membrane layer.
